(19) United States
(12) Patent Application Publication
(10) Pub. No.: US 2025/0262553 A1
(43) Pub. Date: Aug. 21, 2025

(54) COVER AND SYSTEM INCLUDING COVER

(71) Applicant: NINTENDO CO., LTD., Kyoto-shi (JP)

(72) Inventors: Yasuhiro AMANO, Kyoto-shi (JP); Sai TAOKA, Kyoto-shi (JP); Haruki MIYAKE, Kyoto-shi (JP); Saki SHIROMOTO, Kyoto-shi (JP); Kohei ODANAKA, Kyoto-shi (JP)

(21) Appl. No.: 19/202,731

(22) Filed: May 8, 2025

Related U.S. Application Data
(63) Continuation of application No. PCT/JP2022/042091, filed on Nov. 11, 2022.

(51) Int. Cl. A63F 13/98; G06F 1/16

(52) U.S. Cl. CPC A63F 13/98; G06F 1/1629

(57) ABSTRACT

A system includes an electronic apparatus and a cover. The electronic apparatus include: a front surface provided with a display; control parts protruding from the front surface; a back surface opposite to the front surface; a first and second magnetic member provided at edge parts on the front surface side and the back surface side. The back surface has a shape bulging out to a back. The cover includes: a third magnetic member attracted to the first and second magnetic members, and is configured to be attachable to the front and back surfaces of the electronic apparatus by the magnetic members. The cover includes an outer surface which is exposed when the cover is attached to the front or back surface and an inner surface facing the front surface when the cover is attached to the front surface. The inner surface has a shape bulging out in the outer surface direction.

### CROSS-REFERENCE TO RELATED APPLICATION

The present application is a continuation of International Patent Application No. PCT/JP2022/042091 filed on Nov. 11, 2022, which is incorporated herein by reference in their entirety.

### FIELD

The present disclosure relates to a cover and a system including a cover.

### BACKGROUND

Known in the past has been a cover for a portable electronic apparatus (for example, JP 2021-012652 A). The cover described in JP 2021-012652 A has a front cover and back cover connected with each other through a connecting part. In the closed state of this cover accommodating the electronic apparatus therein, the front cover covers the front surface of the electronic apparatus, while the back cover covers the back surface of the electronic apparatus. On the other hand, in the open state of this cover as attached to the electronic apparatus, the back cover is arranged so as to cover the back surface of the electronic apparatus while the front cover is raised up to be separated from the front surface of the electronic apparatus.

### SUMMARY

A cover used for an electronic apparatus is required to be user friendly.

The gist of the present disclosure is as follows.
(1) A system comprising an electronic apparatus and a cover, wherein
the electronic apparatus include:
   a front surface provided with a display;
   control parts protruding forward from the front surface;
   a back surface provided at an opposite side from the front surface;
   a first magnetic member provided at an edge part on the front surface side; and
   a second magnetic member provided at an edge part on the back surface side, the back surface has a shape bulging out backward, the cover includes:
   a third magnetic member attracted to either the first magnetic member or the second magnetic member, the cover being configured to be detachably attached the front surface of the electronic apparatus by the third magnetic member being attracted to the first magnetic member and to be detachably attached to the back surface of the electronic apparatus by the third magnetic member being attracted to the second magnetic member;
   an outer surface which is exposed when the cover is attached to the front surface of the electronic apparatus and when the cover is attached to the back surface of the electronic apparatus; and
   an inner surface facing the front surface of the electronic apparatus when the cover is attached to the front surface and facing the back surface of the electronic apparatus when the cover is attached to the back surface, and
the inner surface having a shape bulging out in a outer surface direction which is a direction from the inner surface toward the outer surface side.
(2) The system according to above (1), wherein the outer surface of the cover has a shape bulging out in the outer surface direction corresponding to the shape of the inner surface.
(3) The system according to above (2), wherein
the control parts protrude to the front at both sides across the display, and
the outer surface and the inner surface of the cover have shapes wherein, compared with a region facing the display when the cover is attached to the front surface, specific regions positioned at both sides across the region bulge out further in the outer surface direction.
(4) The system according to above (3), wherein
the specific regions extend symmetrical across the region facing the display and in directions perpendicular to a direction across the region facing the display.
(5) The system according to above (3) or (4), wherein
the inner surface and the outer surface of the cover bulge out entirely in the outer surface direction and have shapes bulging out further at the specific regions in the outer surface direction compared with other regions of the inner surface and the outer surface.
(6) The system according to above (1) or (2), wherein
the back surface of the electronic apparatus has a shape bulging out backward entirely and the inner surface of the cover has a shape bulging out entirely in the outer surface direction.
(7) The system according to any one of above (1) to (6), wherein
the first magnetic members are arranged along each of opposite sides of the front surface,
the second magnetic members are arranged along each of opposite sides of the back surface, and
the third magnetic members are arranged along each of opposite sides of the cover.
(8) The system according to above (7), wherein
a plurality of the first magnetic members are arranged along each of the opposite sides of the front surface,
a plurality of the second magnetic members are arranged along each of the opposite sides of the back surface,
a plurality of the third magnetic members are arranged along each of the opposite sides of the cover, and
the first magnetic members, the second magnetic members, and the third magnetic members are all magnets, and adjoining magnetic members among the plurality of the magnetic members arranged along each side differ in polarities.
(9) The system according to above (8), wherein
odd numbers of the first magnetic members are arranged along each of the opposite sides of the front surface,
odd numbers of the second magnetic members are arranged along each of the opposite sides of the back surface, and
odd numbers of the third magnetic members are arranged along each of the opposite sides of the cover.
(10) The system according to above (9), wherein
the center-most magnetic member among the odd number of magnetic members arranged along each side are positioned at center of the side.
(11) The system according to above (9) or (10), wherein
a pair of the magnetic members arranged at both sides of the center-most magnetic member among the odd number of magnetic members arranged along each side are positioned at the equal intervals with each other from the center-most magnetic member.
(12) The system according to any one of above (8) to (11), wherein
distances between adjoining magnetic members among magnetic members including the first magnetic members, the second magnetic members, and the third magnetic members are shorter than lengths of the magnetic members along the corresponding sides.
(13) The system according to any one of claims 7 to 12, wherein
the plurality of the first magnetic members are arranged point symmetrically about the center of the front surface, the plurality of the second magnetic members are arranged point symmetrically about the center of the back surface, and the plurality of the third magnetic members are arranged point symmetrically about the center of the cover.
(14) The system according to any one of above (1) to (13), wherein
the electronic apparatus further has a side surface provided between the front surface and the back surface so as to connect the front surface and the back surface, a housing defining the front surface, back surface, and side surface, and a fan provided inside the housing,
the housing has a back wall defining the back surface and bulging out to the back,
the fan is arranged at a region formed inside the housing by the back wall bulging out, and
an air ventilation opening is provided at the side surface, and the air ventilation opening is arranged at a position at least partially overlapping the air ventilation port of the fan when viewing the electronic apparatus from the side surface side where that air ventilation opening is provided.
(15) A cover able to be attached to an electronic apparatus having a front surface provided with a display and a back surface provided at an opposite side from the front surface, which cover:
is configured to be detachably attached to the front surface of the electronic apparatus and to be detachably attached to the back surface of the electronic apparatus,
includes an outer surface which is exposed when the cover is attached to the front surface of the electronic apparatus and when the cover is attached to the back surface of the electronic apparatus,
includes an inner surface facing the front surface and back surface when the cover is attached to the front surface of the electronic apparatus and when the cover is attached to the back surface of the electronic apparatus and having a shape bulging out in an outer surface direction which is a direction toward the outer surface side with respect to the cover, and
third magnetic member attracted to first magnetic member provided at an edge part of a front surface side of the electronic apparatus and to second magnetic member provided at an edge part at a back surface side of the electronic apparatus.

### BRIEF DESCRIPTION OF DRAWINGS

Embodiments of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view schematically showing an apparatus-cover system.

FIG. 2 is a perspective view schematically showing an apparatus-cover system.

FIG. 3 is a front view, top view, bottom view, and left side view of an electronic apparatus.

FIG. 4 is a perspective view of the electronic apparatus seen from the left rear.

FIG. 5 is a plan view of an electronic apparatus.

FIG. 6 is an enlarged cross-sectional view of an electronic apparatus seen along a line VI-VI of FIGS. 4 and 5.

FIG. 7 is a cross-sectional view of an electronic apparatus seen along a line VII-VII of FIG. 5.

FIG. 8 is a perspective view of an inner surface side of a cover.

FIG. 9 is a plan view of a cover.

FIG. 10 is an enlarged cross-sectional view of a cover seen along a plane X-X of FIGS. 8 and 9.

FIG. 11 is a cross-sectional view of an electronic apparatus and cover when the cover is attached to a front surface of the electronic apparatus.

FIG. 12 is a cross-sectional view of an electronic apparatus and cover when the cover is attached to a back surface of the electronic apparatus.

FIG. 13 is a plan view, similar to FIG. 5, of an electronic apparatus.

FIG. 14 is a plan view, similar to FIG. 9, of a cover.

FIG. 15 is a perspective view, similar to FIG. 8, of an inner surface side of a cover according to a second embodiment.

FIG. 16 is an cross-sectional view of a cover according to the second embodiment seen along a plane XVI-XVI of FIG. 15.

### DESCRIPTION OF EMBODIMENTS

Below, referring to the drawings, embodiments will be explained in detail. It should be noted that in the following explanation, similar component elements will be assigned the same reference numerals.

### First Embodiment

### Apparatus-Cover System

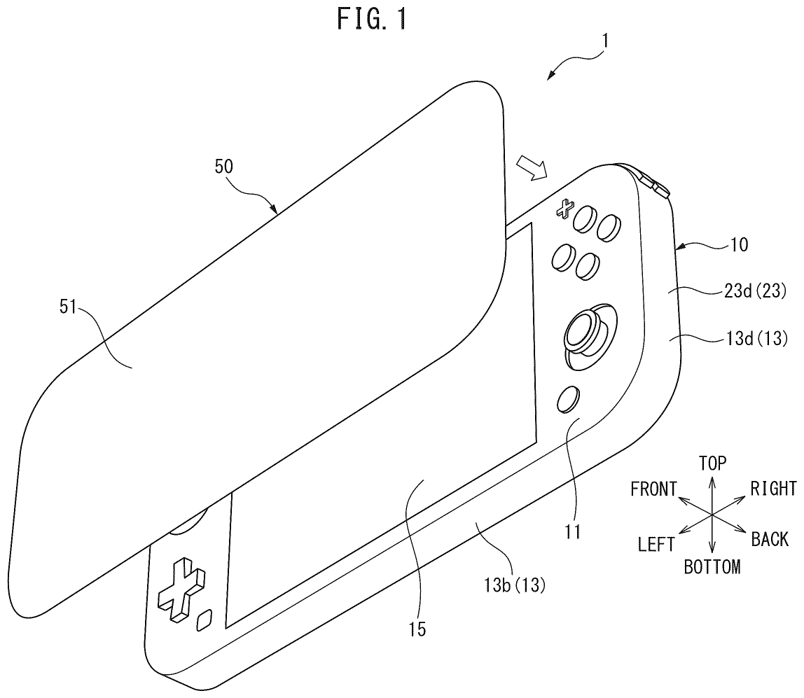

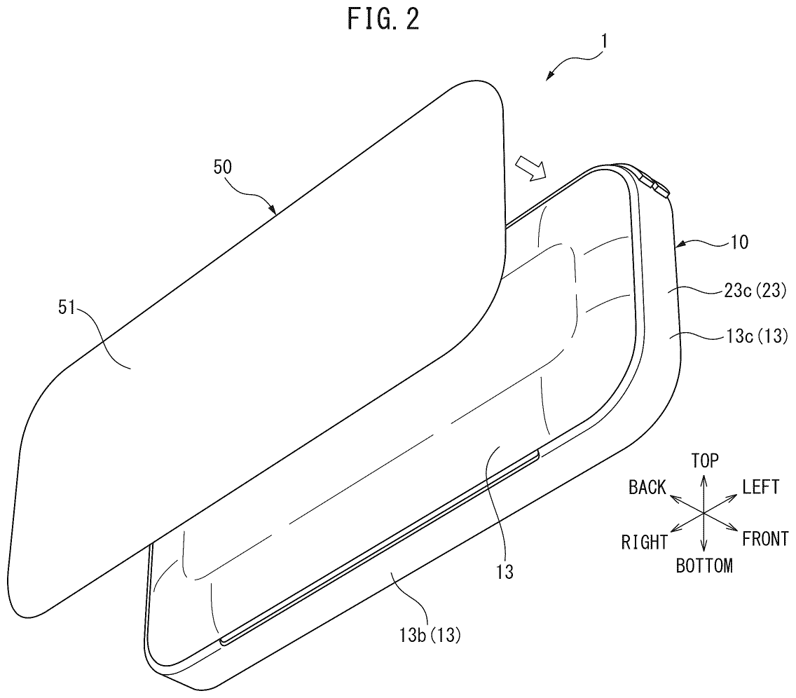

Referring to FIGS. 1 and 2, the overall configuration of an apparatus-cover system 1 according to a first embodiment will be explained. The apparatus-cover system 1 includes an electronic apparatus 10 and a cover 50. The electronic apparatus 10 is an apparatus including a display 15 and having a substantially cuboid shape with rounded corners. In particular, in the present embodiment, the electronic apparatus 10 is a portable apparatus which a user can use while holding it. The electronic apparatus 10 is for example a portable game machine, tablet, etc.

FIGS. 1 and 2 are perspective views schematically showing an apparatus-cover system 1. In FIG. 1, a front surface of the electronic apparatus 10 is shown, while in FIG. 2, a back surface of the electronic apparatus 10 is shown. As shown in FIGS. 1 and 2, the display 15 is provided at one surface of the electronic apparatus 10 having the substantially cuboid shape.

In this Description, the direction at which the display 15 is provided at the electronic apparatus 10 is referred to as the “front”, while the opposite direction to the direction at which the display 15 is provided is referred to as the “back”. Further, the top direction, bottom direction, left direction, and right direction seen from the front when the user is holding the electronic apparatus 10 and viewing the display 15 are respectively referred to as the “top”, “bottom”, “left”, and “right” of the electronic apparatus 10.

As shown in FIGS. 1 and 2, the electronic apparatus 10 has a front surface 11 provided with the display 15, a back surface 12 provided at an opposite side to the front surface, and a side surface 13 formed between the front surface 11 and back surface 12 so as to connect the front surface 11 and back surface 12. The side surface 13 includes a top surface 13a provided at the top of the electronic apparatus 10, a bottom surface 13b provided at the bottom of the electronic apparatus 10, a left surface 13c provided at the left of the electronic apparatus 10, and a right surface 13d provided at the right of the electronic apparatus 10. It should be noted that, if changing the way of looking at it, the direction of the front surface 11 side of the electronic apparatus 10 can be referred to as the “front” and the direction of the back surface 12 side of the electronic apparatus 10 can be referred to as the “back”.

The cover 50 is configured to be detachably attached to the front surface 11 of the electronic apparatus 10. Therefore, by being moved from the state shown in FIG. 1 in the direction shown by the arrow in the figure, the cover 50 can be attached to the front surface 11 of the electronic apparatus 10 so as to cover the front surface 11. By the cover 50 being attached to the front surface 11 of the electronic apparatus 10 in this way, the display 15 or the like provided at the front surface 11 of the electronic apparatus 10 can be protected.

Similarly, the cover 50 is configured to be detachably attached to the back surface 12 of the electronic apparatus 10. Therefore, by being moved from the state shown in FIG. 2 in the direction shown by the arrow in the figure, the cover 50 can be attached to the back surface 12 of the electronic apparatus 10 so as to cover the back surface 12. By the cover 50 being attached to the back surface 12 of the electronic apparatus 10 in this way, the user can hold the cover 50 integrally with the electronic apparatus 10 while he or she is using the electronic apparatus 10 and, accordingly, the cover 50 can be kept from being lost. Further, depending on the material or shape of the cover 50, the user can comfortably hold the electronic apparatus 10 and the cover 50.

### Electronic Apparatus

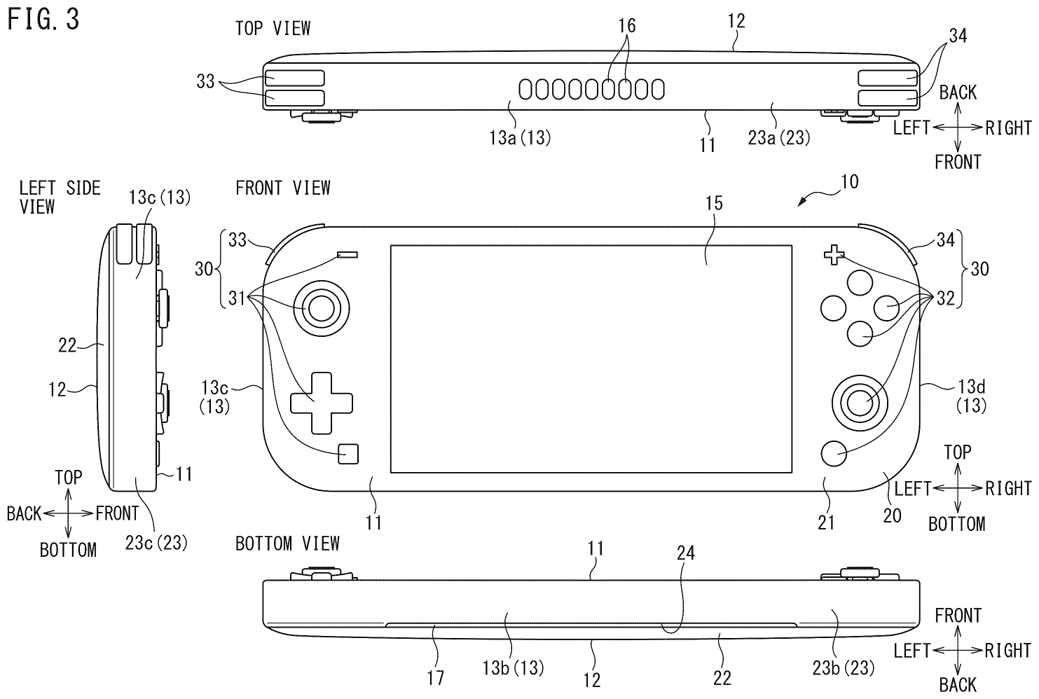

Next, referring to FIGS. 3 to 7, the configuration of the electronic apparatus 10 will be explained. FIG. 3 is a front view, top view, bottom view, and left view of the electronic apparatus 10. As shown in FIG. 3, the electronic apparatus 10 has a housing 20, display 15, a plurality of control parts 30, and magnets 41, 42.

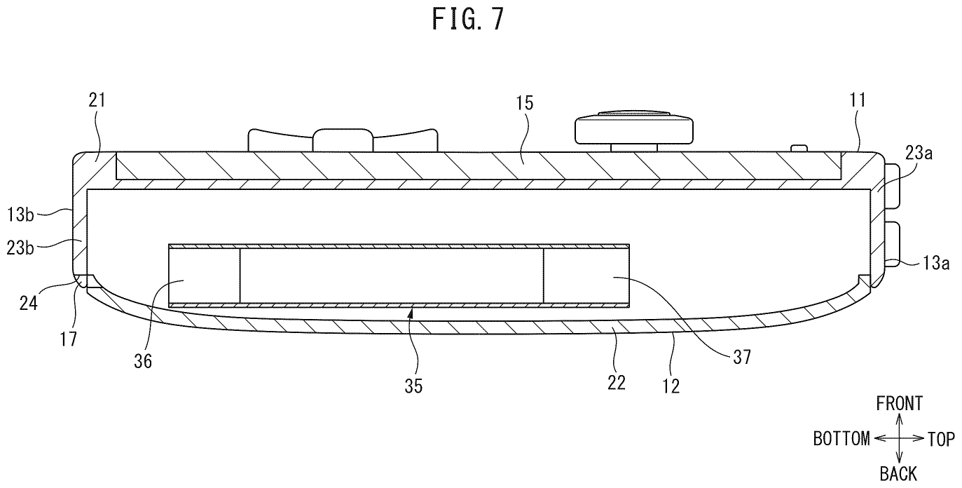

The housing 20 accommodates a circuit board and electronic components forming the electronic apparatus 10. The electronic components include a control device (processor or the like) of the electronic apparatus 10 controlling the display or the like, a memory storing various data used in the control device, a battery supplying power to the display 15, control device and the like (all not shown), a fan 35 ventilating air inside the housing (see FIG. 7), etc. The housing 20 has a front wall 21 provided at the front side of the electronic apparatus 10, a back wall 22 provided at the back side of the electronic apparatus 10, and a side wall 23 provided between the front wall 21 and the back wall 22. The side wall 23 includes a top wall 23a provided at the top of the electronic apparatus 10, a bottom wall 23b provided at the bottom of the electronic apparatus 10, a left wall 23c provided at the left of the electronic apparatus 10, and a right wall 23d provided at the right of the electronic apparatus 10.

In the present embodiment, the surface at the front of the front wall 21 defines the front surface 11 of the electronic apparatus 10 while the surface at the back of the back wall 22 defines the back surface 12 of the electronic apparatus 10. Further, in the present embodiment, the surface at the top of the top wall 23a, the surface at the bottom of the bottom wall 23b, the surface at the left of the left wall 23c, and the surface at the right of the right wall respectively define the top surface 13a, bottom surface 13b, left surface 13c, and right surface 13d of the electronic apparatus 10. Therefore, the housing 20 defines the front surface 11, back surface 12, and side surface 13 of the electronic apparatus 10. In the present embodiment, the front wall 21 and the side wall 23 are integrally formed. The housing 20 is formed by attaching a separate back wall 22 to the side wall 23. In another embodiment, the front wall 21 and part of the side wall 23 are integrally formed, the back wall 22 and the remaining part of the side wall 23 are integrally formed, and the part of the side wall 23 integrally formed with the front wall 21 and the part of the side wall 23 integrally formed with the back wall 22 can be connected to thereby form the housing 20.

The front surface 11 of the electronic apparatus 10 is formed substantially flat entirely. Further, the front surface 11 of the electronic apparatus 10, when viewed from the front, has a rectangular shape with rounded corners. The sides positioned at the top and bottom form long sides while the sides positioned at the left and right form short sides. At the center of the rectangular shaped front surface 11, the display 15 is provided. Further, in the present embodiment, the front surface 11 is provided with the later explained control parts 30.

On the other hand, in the same way as the front surface 11, the back surface 12 of the electronic apparatus 10, when viewed from the back, has a rectangular shape with rounded corners. The sides positioned at the top and bottom form long sides while the sides positioned at the left and right form short sides. Further, the back surface 12, as will be understood from the bottom view and left side view of FIG. 3, has a shape entirely bulging out toward the back (that is, in the electronic apparatus 10, toward the direction of the back surface 12 side). In the present embodiment, the back surface 12 has a shape with a large curvature near the peripheral edges and with a curvature becoming smaller toward the center from the peripheral edges. In particular, in the present embodiment, the back surface 12 has a shape with a relatively large curvature at regions within a certain distance from the long sides and short sides, and with a relatively small or zero curvature at regions separated by greater than or equal to a certain distance from the long sides and short sides. Further, in the present embodiment, the back wall 22 also has a shape bulging out toward the back corresponding to the bulging shape of the back surface 12.

The side surface 13 of the electronic apparatus 10 extends substantially perpendicular with respect to the front surface 11 between the edge of the front surface 11 and the edge of the back surface 12. The top surface 13a extends between the long sides of the top sides of the front surface 11 and back surface 12, while the bottom surface 13b extends between the long sides of the bottom sides of the front surface 11 and back surface 12. The left surface 13c extends between the short sides of the left sides of the front surface 11 and back surface 12, while the right surface 13d extends between the short sides of the right sides of the front surface 11 and back surface 12. In the present embodiment, the top surface 13a is curved toward the left surface 13c and the right surface 13d so as to match the shapes of the rounded corner parts of the front surface 11 and back surface 12. Similarly, the bottom surface 13b is curved toward the left surface 13c and the right surface 13d so as to match the shapes of the rounded corner parts of the front surface 11 and back surface 12.

In the present embodiment, as will be understood from the top surface view of FIG. 3, the top surface 13a is provided with exhaust openings 16 for exhausting air inside the electronic apparatus 10 to the outside. The exhaust openings 16 are arranged at the center of the top surface 13a in the left-right direction. The exhaust openings 16 pass through the top wall 23a and are formed at the top wall 23a so that the inside of the electronic apparatus 10 is communicated with the outside. In the present embodiment, a plurality of exhaust openings 16 are provided at the top surface 13a, but other shape of exhaust opening, such as one large exhaust opening, may be provided.

Further, as will be understood from the bottom view of FIG. 3, the bottom surface 13b is provided with an intake opening 17 for intaking outside air to the inside of the electronic apparatus 10. In the present embodiment, a single intake opening 17 extending to the left and right is provided at the center of the bottom surface 13b in the left-right direction. Further, in the present embodiment, the intake opening 17 is arranged at the back surface side in the front-back direction, in particular adjoining the back surface. Specifically, in the present embodiment, a cutaway 24 extending in the left-right direction is provided at the center in the left-right direction at the back surface side of the bottom wall 23b. This cutaway 24 extends from the back end of the bottom wall 23b toward the front. Therefore, when the back wall 22 is attached to the side wall 23, the back of the cutaway 24 is closed by the back wall 22. As a result, the cutaway 24 and the back wall 22 define the intake opening 17. It should be noted that, in another embodiment, an intake opening passing through the bottom wall 23b (that is, an intake opening defined by only the bottom wall 23b) may be provided between the outside space and the inside space of the housing 20.

It should be noted that, exhaust openings for exhausting air inside of the electronic apparatus 10 to the outside may be provided at the position of the intake opening 17 instead of the intake opening 17. Similarly, an intake opening for intaking outside air into the electronic apparatus 10 may be provided at the position of the exhaust openings 16 instead of the exhaust openings 16. Therefore, it can be said that air ventilation openings are provided for ventilating air between the inside of the electronic apparatus 10 (inside of the housing 20) and the outside thereof at the positions of the ventilation opening 16 and intake opening 17. Further, air exchange openings may be provided at side surfaces 13 other than the top surface 13a and the bottom surface 13b or at the back surface 12.

In addition, in the present embodiment, later explained control parts 30 are arranged at the side surface 13. Furthermore, various other elements may be provided at the side surface 13. For example, a headphone jack terminal, connection terminal such as USB terminal, a slot for insertion of a storage medium (memory card or the like) for storing a game program or data, openings for a speaker built into the electronic apparatus 10, etc., my be provided at the side surface 13.

The display 15 is an apparatus connected to a control device arranged inside the housing 20 and showing an image corresponding to a signal from the control device (still image or moving image). The display 15 is mounted at the front surface of a recess recessed to the back in the front wall 21 of the housing 20 and forms part of the front surface 11 of the electronic apparatus 10. The display 15 has a substantially flat surface. The display 15 is for example a liquid crystal display, EL (electroluminescence) display, or plasma display. The display 15 may be provided on its surface with a touch panel functioning as an input device. Further, the display 15 may be suitably attached to the electronic apparatus 10 so that the display surface thereof is exposed from an aperture provided at the front wall 21.

The control parts 30 are operated by the user and function as input devices for input to the electronic apparatus 10. The control parts 30 are connected to a control device inside the electronic apparatus 10 and input signals corresponding to operations by the user to the control device. The control parts 30 can for example include buttons, switches, levers, a joystick, etc. Further, the buttons may be shaped as circular, rectangular, oval, crossed, and various other shapes.

As shown in FIG. 3, in the present embodiment, the electronic apparatus 10 includes a plurality of control parts 30. In the example shown in FIG. 3, at the front surface 11, a plurality of first control parts 31 are provided at the left side of the display 15 and a plurality of second control parts 32 are provided at the right side of the display 15. Therefore, at the front surface 11, control parts 30 are provided at both of the left and right sides across the display 15. These first control parts 31 and second control parts 32 are arranged so as to protrude from the front surface 11 to the front. Further, the first control parts 31 and second control parts 32 are arranged at substantially equal distances from the center of the front surface 11 in the left-right direction.

Further, in the example shown in FIG. 3, at the top surface 13a positioned at the left side from the display 15, in particular at the part curved to the left surface 13c, a plurality of third control parts 33 are provided. In addition, at the top surface 13a positioned at the right side from the display 15, in particular at the part curved to the right surface 13d, a plurality of fourth control parts 34 are provided. Therefore, at the side surface 13, the control parts 30 are provided at both of the left and right sides of the display 15. It should be noted that, in another embodiment, the third control parts 33 and the fourth control parts 34 may be provided at only the flat region at the inside from the curved parts in the top surface 13a.

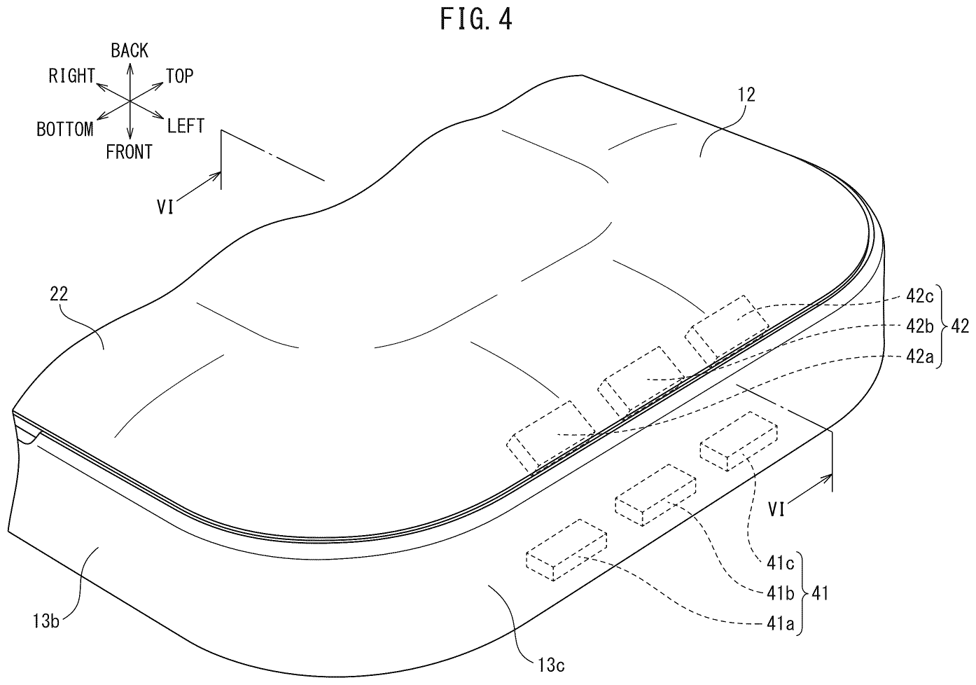

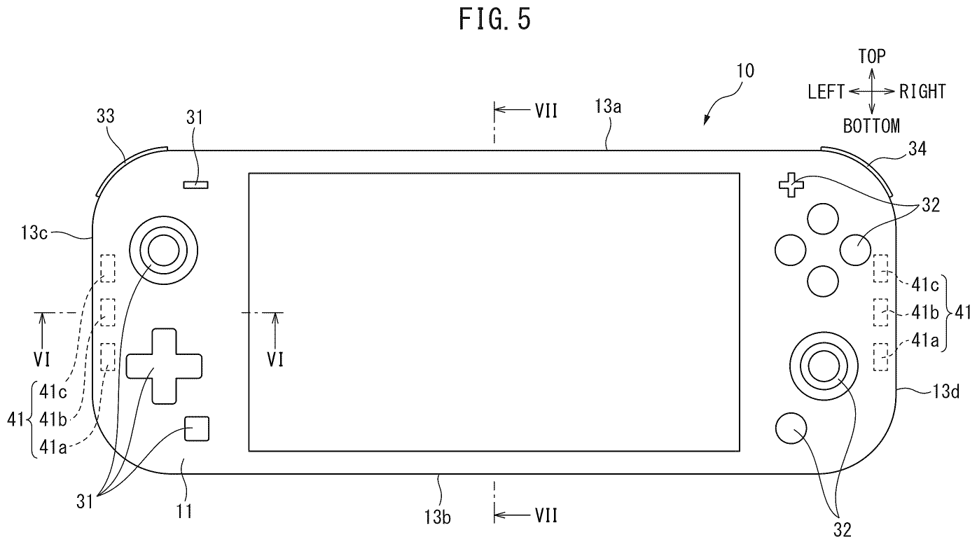

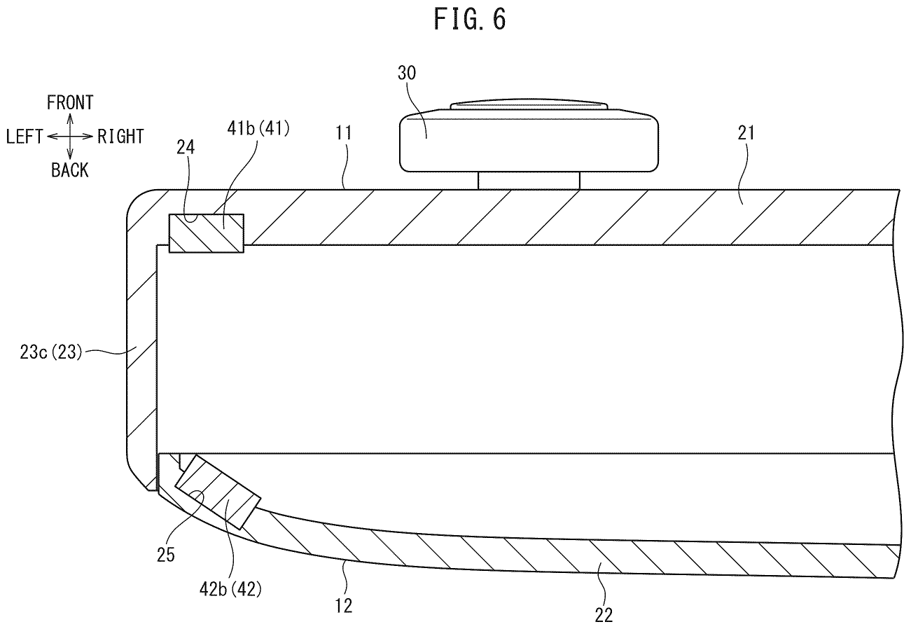

Next, referring to FIGS. 4 to 6, the magnets 41, 42 provided at the electronic apparatus 10 will be explained. FIG. 4 is a perspective view of the electronic apparatus 10 seen from the left rear. FIG. 5 is a plan view of the electronic apparatus 10. FIG. 6 is an enlarged cross-sectional view of the electronic apparatus 10 seen along the line VI-VI of FIGS. 4 and 5. The broken lines in FIGS. 4 and 5 show the magnets 41, 42.

The magnets 41, 42 of the electronic apparatus 10 are used for attaching the cover 50 to the electronic apparatus 10. That is, the cover 50 is attached to the electronic apparatus 10 by the later mentioned magnets 61 of the cover 50 being attracted to the magnets 41, 42 of the electronic apparatus 10. In the present embodiment, as shown in FIGS. 4 and 6, the electronic apparatus 10 has the first magnets 41 provided at edge parts of the front surface 11 side (front side from center in front-back direction) of the electronic apparatus 10 (region including edge of front surface 11 side of the electronic apparatus 10 and its vicinity) and second magnets 42 provided at edge parts of the back surface 12 side (back side from center in front-back direction) of the electronic apparatus 10 (region including edge of back surface 12 side of the electronic apparatus 10 and its vicinity).

As shown in FIG. 5, a plurality of first magnets 41 are arranged along the left short side of the front surface 11 and a plurality of first magnets 41 are arranged along the right short side of the front surface 11. Therefore, the first magnets 41 are respectively arranged at the opposite short sides of the front surface 11. These first magnets 41 are arranged at the outside from the control parts 30 provided at the front surface 11. In particular, in the present embodiment, three first magnets 41 are arranged along either of the short sides. It should be noted that, odd numbers of first magnets 41 of other than three may be arranged respectively along each corresponding short side. Further, the second magnets 42 are arranged in positional relationships similar to the first magnets 41 (interval in left-right direction and interval in top-bottom direction).

A plurality of second magnets 42 are arranged along the left short side of the back surface 12 and a plurality of second magnets 42 are arranged along the right short side of the back surface 12. Therefore, the second magnets 42 are respectively arranged at the opposite short sides of the back surface 12. In particular, in the present embodiment, three second magnets 42 are arranged along either of the short sides. It should be noted that, odd numbers of second magnets 42 of other than three may be arranged respectively along each corresponding short side.

In the present embodiment, as shown in FIG. 6, the first magnets 41 are attached at the inside of the front wall 21 defining the front surface 11. Further, the first magnets 41 are attached so as to extend in the left-right direction in parallel with the front surface 11. In particular, in the present embodiment, first recesses 24 are formed at the inner surface of the front wall 21 in proximity to the side wall 23 along the side wall 23. The first magnets 41 are fastened inside the first recesses 24. It should be noted that, the first magnets 41 may be attached at the inside of the side wall 23 in the vicinity of the front wall 21 or may be attached at corner parts defined by the inner surface of the front wall 21 and the inner surface of the side wall 23.

Similarly, in the present embodiment, the second magnets 42 are attached at the inside of the back wall 22 defining the back surface 12. Further, the seconds magnets 42 are attached so as to extend along the curved back surface 12 with an angle with respect to the left-right direction. In particular, in the present embodiment, second recesses 25 are formed at the inner surface of the back wall 22 in proximity to the side wall 23 along the side wall 23. The second magnets 42 are fastened inside the second recesses 25. It should be noted that, the first magnets 41 may be attached at the inside of the side wall 23 in the vicinity of the front wall 21 or may be attached to the corner parts defined by the inner surface of the front wall 21 and the inner surface of the side wall 23. It should be noted that, the specific arrangement of the first magnets 41 and second magnets 42 will be explained later.

It should be noted that, elements besides the display 15 and control parts 30 may be provided at the front surface 11 or back surface 12 of the electronic apparatus 10. Specifically, for example, a camera (not shown) may be provided at the front surface 11 or back surface 12 or both of the front surface 11 and back surface 12.

Next, referring to FIG. 7, the fan 35 provided in the housing 20 will be explained. FIG. 7 is a cross-sectional view of the electronic apparatus 10 seen along the line VII-VII of FIG. 5. It should be noted that, in FIG. 7, to facilitate understanding of the drawings, only a fan 35 is drawn as electronic components provided inside the housing 20. However, as explained above, other electronic components, such as a processor and memory, circuit board, and the like are housed inside the housing 20.

The fan 35 ventilates air inside the housing 20. The fan 35 sucks in outside air to the inside of the housing through the intake opening 17 formed in the bottom surface 13b of the electronic apparatus 10. Further, the fan 35 exhausts air inside the housing 20 to the outside through exhaust openings 16 formed in the top surface 13a. As a result, the electronic components inside the housing 20 are cooled.

As shown in FIG. 7, the fan 35 is provided inside the housing 20 at the back surface 12 side. In particular, in the present embodiment, the fan 35 is provided adjoining the back wall 22 defining the back surface 12. Further, in the present embodiment, the fan 35 is arranged in the top-bottom direction separated by a certain extent from both the top wall 23a and the bottom wall 23b. For this reason, in the present embodiment, the fan 35 is arranged in a region inside the back wall 22 formed by the back wall 22 having the shape bulging out toward the back.

The fan 35 has an intake port 36 for intake and an exhaust port 37 for exhaust. In the present embodiment, the intake port 36 is arranged below the fan 35, while the exhaust port 37 is arranged above the fan 35. Therefore, the intake port 36 is arranged so as to face the intake opening 17. In addition, in the present embodiment, the fan 35 is arranged so that, when viewed in the top-bottom direction (in particular, when viewed from the bottom surface 13b side where the intake opening 17 is provided), the intake port 36 of the fan 35 partially overlaps the intake opening 17. It should be noted that, it may be configured so that the intake port 36 of the fan 35 completely overlaps the intake opening 17.

It should be noted that, in the present embodiment, the intake port 36 is arranged so as to face the intake opening 17. However, the exhaust port 37 may be arranged so as to face the intake opening (air ventilation opening) 17. In this case as well, when viewed from the side surface where the air ventilation opening 17 is provided, the fan 35 is arranged so that the exhaust port 37 of the fan 35 at least partially overlaps the air ventilation opening 17. That is, the air ventilation opening 17 is arranged at a position at least partially overlapping the air ventilation port of the fan 35.

### Cover

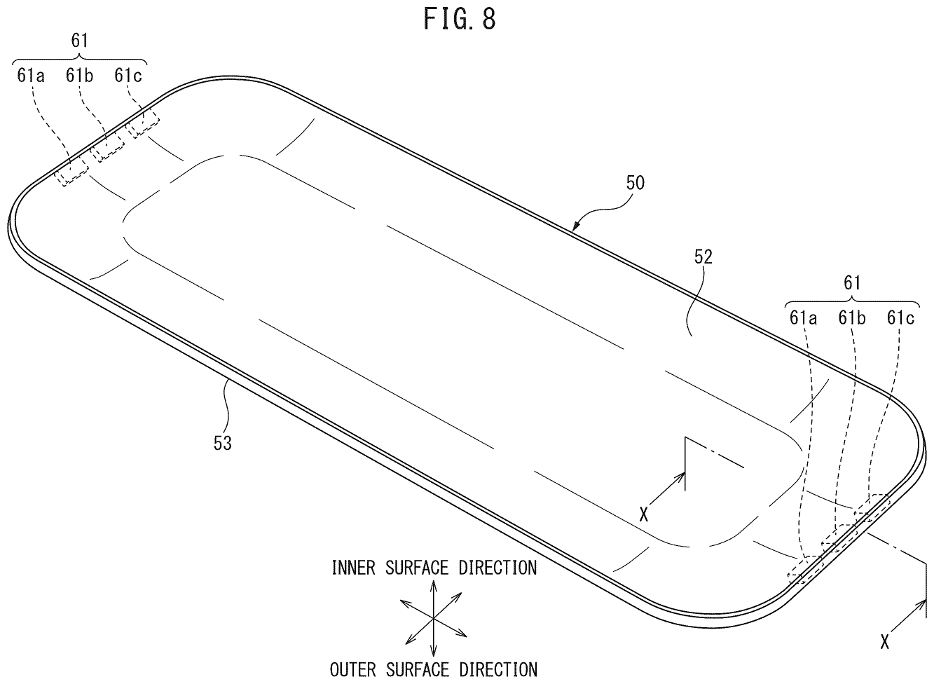

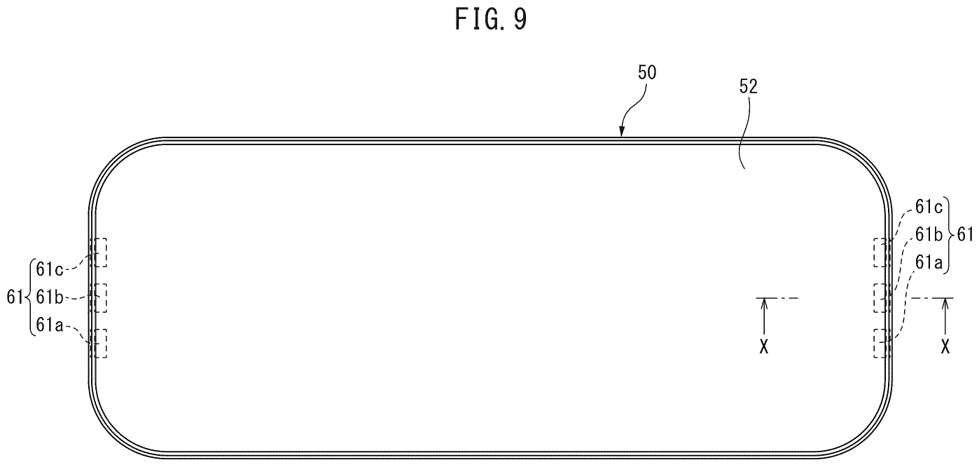

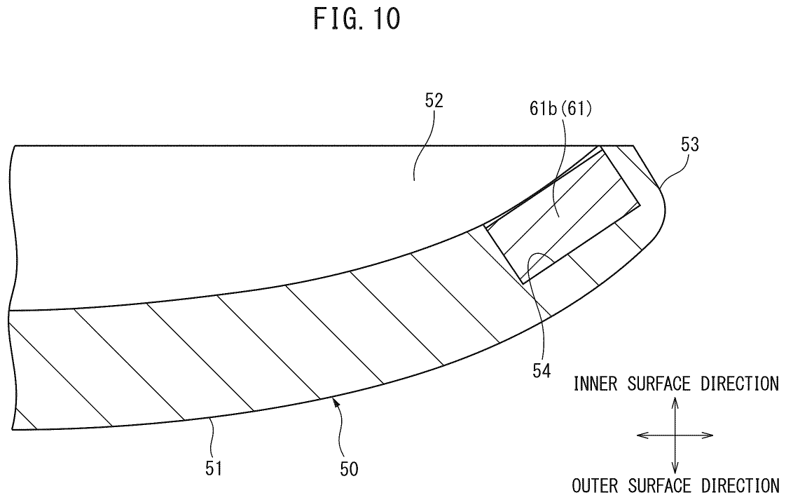

Next, referring to FIGS. 1, 2, and 8 to 10, the configuration of the cover 50 will be explained. FIG. 8 is a perspective view of an inner surface side of the cover 50, FIG. 9 is a plan view of the cover 50, and FIG. 10 is an enlarged cross-sectional view of the cover 50 seen along a plane X-X of FIGS. 8 and 9. It should be noted that, in FIGS. 8 and 9, the cover 50 has a sheet covering the entire cover 50. For this reason, in FIGS. 8 and 9, the magnets 61 do not appear at the surface of the cover 50 and accordingly are shown by broken lines. On the other hand, FIG. 10 shows the cover in the state not having the sheet. Accordingly, the magnets 61 are exposed to the outside.

The cover 50 is a plate-shaped member and has an outer surface 51, an inner surface 52 at the opposite side from the outer surface 51, and a side surface 53 formed between these outer surface 51 and inner surface 52 so as to connect the outer surface 51 and inner surface 52. As will be understood from FIGS. 1 and 2, the outer surface 51 is exposed to the outside when the cover 50 is attached to the front surface 11 or back surface 12 of the electronic apparatus 10. On the other hand, the inner surface 52 faces the front surface 11 or back surface 12 when the cover 50 is attached to the front surface 11 or back surface 12 of the electronic apparatus 10. It should be noted that, in this Description, the direction of the outer surface 51 side from the cover 50 will be referred to as the “outer surface direction” and the direction of the inner surface 52 side at the cover 50 will be referred to as the “inner surface direction.”

When viewed in the outer surface direction and inner surface direction, the cover 50 has a rectangular shape with rounded corners similarly to the electronic apparatus 10. Therefore, the outer surface 51 and inner surface 52 of the cover 50 have rectangular shapes with rounded corners. Further, as will be understood from FIG. 8, the cover 50 has a shape bulging out entirely in the outer surface direction. Therefore, in the present embodiment, each of the outer surface 51 and inner surface 52 has a shape bulging out entirely in the outer surface direction. In particular, in the present embodiment, the bulging shapes of the outer surface 51 and inner surface 52 have shapes similar to the bulging shape of the back surface 12 of the electronic apparatus 10. Further, in the present embodiment, the outer surface 51 and inner surface 52 have shapes with large curvature near the peripheral edges and with curvature becoming smaller from the peripheral edges toward the centers. In particular, in the present embodiment, the outer surface 51 and inner surface 52 have shapes with relatively large curvature at regions within certain distances from the long sides and short sides and with relatively small or zero curvature at regions separated from the long sides and short sides by certain distances or more. Further, in the present embodiment, the inner surface 52 has a shape complementary with the bulging shape of the back surface 12 of the electronic apparatus 10.

It should be noted that, in the present embodiment, the outer surface 51 of the cover 50 has a shape bulging out in the outer surface direction corresponding to the shape of the inner surface 52. However, so long as the inner surface 52 has a shape bulging out in the outer surface direction, the cover 50 may have a different shape such as a flat shape. Therefore, in the present embodiment, the cover 50 has entirely an even thickness, but it may have thicknesses differing depending on the region.

Further, the cover 50 has third magnets 61 used for attaching the cover 50 to the electronic apparatus 10. The third magnets 61 are provided at the edge parts of the cover 50 on the inner surface 52 side (regions including edges of inner surface 52 and their vicinity).

A plurality of third magnets 61 are arranged along one short side of the inner surface 52 and a plurality of third magnets 61 are also arranged along the other short side of the inner surface 52. Therefore, the third magnets 61 are arranged at each of opposite sides of the inner surface 52 of the cover 50. In particular, in the present embodiment, three third magnets 61 are arranged along each of the short sides. It should be noted that, odd numbers of other than three third magnets 61 may be arranged along each short side. Further, the third magnets 61 are arranged in positional relationships similar to the first magnets 41 and second magnets 42 (intervals in long side direction and intervals in short side direction).

Further, in the present embodiment, the third magnets 61 are attached to the cover 50 at the inner surface 52 side. The third magnets 61 are attached so as to extend by an angle with respect to a plane defined by the edges as a whole of the inner surface 52 (that is, a plane when placing the cover 50 on the plane so that the inner surface 52 contacts the plane) along the curved inner surface 52. In particular, in the present embodiment, as shown in FIG. 10, third recesses 54 are formed at the inner surface 52 of the cover 50 along the side surface 53 in proximity to the side surface 53. The third magnets 61 are fixed inside the third recesses 54. It should be noted that, the third magnets may be attached to the cover 50 at the outer surface 51 side. In this case, the third magnets are fixed inside recesses provided at the outer surface 51 of the cover 50. Further, the third magnets may be attached to the cover 50 at the side surface 53.

### Arrangement of Magnets

Next, referring to FIG. 4 to FIG. 9, the arrangement of the magnets 41, 42, 61 will be explained. As explained above, in the present embodiment, three the magnets 41, 42, 61 are arranged along the corresponding each short side (that is, the short sides of the front surface 11, the short sides of the back surface 12, and the short sides of the inner surface 52). Below, the three magnets arranged aligned are have “a”, “b”, and “c” appended to their notations in that order (for example, the first magnets 41 arranged along one side are represented as 41a, 41b, 41c in that order. Further, the magnets of the electronic apparatus 10 are represented by “a”, “b”, and “c” from below to above in that order).

In the present embodiment, as shown in FIGS. 4, 5, 8, and 9, the center-most magnet 41b, 42b, 61b among the odd numbers of magnets 41, 42, and 61 arranged along the each short side are arranged so as to be positioned at the center of the short side. In addition, the odd numbers of magnets 41, 42, 61 arranged along each short side are arranged so that adjoining magnets 41, 42, 61 are positioned at equal intervals from each other. Therefore, in the present embodiment, the odd numbers of magnets 41, 42, 61 arranged along each side are arranged so that a pair of magnets arranged at both sides of the center-most magnets 41b, 42b, 61b (a magnet positioned at center of short side) (in the example shown in FIG. 4, the pair of the magnets adjoining, in top and bottom sides, the magnet positioned at the centers, therefore, the pair of 41a and 41c, the pair of 42a and 42c, and the pair of 61a and 61c) are positioned at equal intervals from the center-most magnets 41b, 42b, 61b. It should be noted that, when the number of magnets 41, 42, 61 arranged along each short side is odd numbers greater than 3, they are arranged so that a plurality of pairs are formed for each side and the plurality of pairs are all positioned at equal intervals from the center-most magnet.

In addition, in the present embodiment, the magnets 41, 42, or 61 are formed in cuboid shapes. In the present embodiment, the first magnets 41, second magnets 42, and third magnets 61 all have exactly the same shapes and are arranged so as to extend along the short sides of the front surface 11, back surface 12, or inner surface 52. That is, the magnets 41, 42, 61 are respectively arranged so that their longest sides extend in parallel with the short sides of the front surface 11, back surface 12, or inner surface 52. In addition, the magnets 41, 42, or 61 are arranged so that the distances between adjoining magnets become shorter than the lengths of the magnets 41, 42, 61 along the corresponding short sides (in the present embodiment, the lengths of the longest sides of the magnets 41, 42).

Further, in the present embodiment, the adjoining magnets among the magnets 41, 42, 61 arranged along each short side are arranged so that their polarities differ. Specifically, in the present embodiment, they are arranged so that the polarities of the front surface 11 sides of the magnets 41, the back surface 12 sides of the magnets 42, and the inner surface 52 sides of the magnets 61 are different between adjoining magnets. Therefore, for example, if the front surface 11 sides of the center-most first magnets 41b are S poles, the front surface 11 sides of the first magnets 41a, 41c positioned at the two sides are N poles.

Furthermore, in the present embodiment, when the cover 50 is positioned at the attachment position on the front surface 11 of the electronic apparatus 10, the first magnets 41 have polarities different from the corresponding third magnets 61. Specifically, the polarity of the front side of the center-most first magnet 41b among the first magnets 41 arranged along each side differ from the polarity of the inner surface side of the center-most magnet 61b among the third magnet 61 arranged along each side of the cover 50. Further, the polarities of the front side of the first magnets 41a, 41c at both ends among the first magnets 41 arranged along each side differ from the polarities of the inner surface sides of the third magnets 61a, 61c at the both ends among the third magnets 61 arranged along each side of the cover 50. Similarly, when the cover 50 is positioned at the attachment position on the back surface 12 of the electronic apparatus 10, each second magnet 42 has polarity different from that of the corresponding third magnet 61.

In addition, in the present embodiment, when viewed in the front-back direction (when viewed in direction of FIG. 5), the first magnets 41 are arranged point symmetrically about a center of the front surface 11, and the second magnets 42 are arranged point symmetrically about a center of the back surface 12. Further, when viewed in the inner surface/outer surface direction (when viewed in direction of FIG. 9), the third magnets 61 are arranged point symmetrically about a center of the inner surface 52 (that is, about the center of the cover 50). As a result, in the present embodiment, even if the electronic apparatus 10 is rotated by 180° about the center of the front surface 11 and back surface 12, the first magnets 41 and second magnets 42 become arranged the same. Similarly, even if the cover 50 is rotated by 180° about the center of the cover 50, the arrangement of the third magnets 61 becomes the same.

### Attachment of Cover

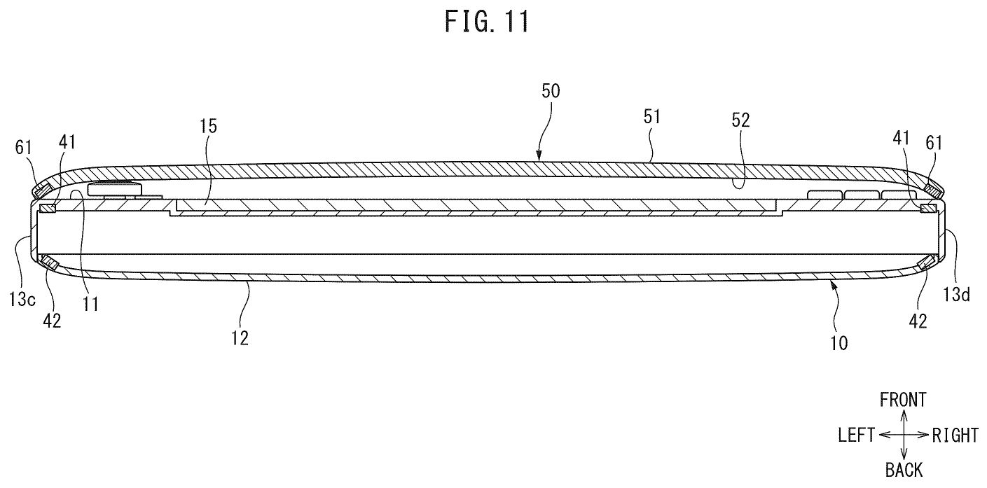

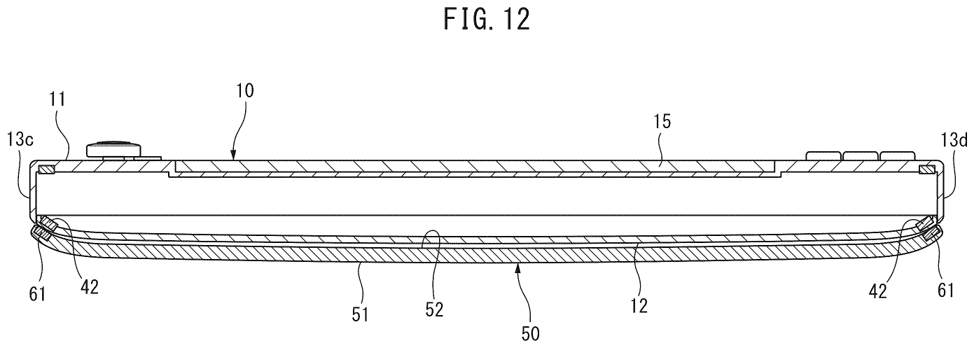

Next, referring to FIGS. 11 and 12, the state of the cover 50 and electronic apparatus 10 when the cover 50 is attached to the front surface 11 and back surface 12 of the electronic apparatus 10 will be explained.

FIG. 11 is a cross-sectional view of the electronic apparatus 10 and the cover 50 when the cover 50 is attached to the front surface 11 of the electronic apparatus 10. As shown in FIG. 11, when attached to the front surface 11, the cover 50 is configured to contact the front surface 11 at the edges of the inner surface 52 and not to contact the front surface 11 at other regions. As a result, when the cover 50 is attached to the front surface 11, a space is formed between the front surface 11 and the inner surface 52 of the cover 50. In particular, in the present embodiment, the inner surface 52 is made to bulge out so that the cover 50 does not interfere with the control parts 30 or the cover 50 does not excessively interfere with the control parts 30 when the cover 50 is attached to the front surface 11.

It should be noted that, in the present embodiment, when attached to the front surface 11, the cover 50 linearly contacts the front surface 11 at the edges of the inner surface 52, but it may planarly contact the front surface 11 at the edge parts of the inner surface 52 (regions including edges and their vicinity). Alternatively, the cover 50 may linearly contact the edges of the side surface 53 or planarly contact the front surface 11 at the side surface 53 as a whole.

FIG. 12 is a cross-sectional view of the electronic apparatus 10 and the cover 50 when the cover 50 is attached to the back surface 12 of the electronic apparatus 10. As shown in FIG. 12, the inner surface 52 of the cover 50 extends along the back surface 12 bulging out from the electronic apparatus 10. Further, in the present embodiment, when attached to the back surface 12, the cover 50 contacts the back surface 12 at the edge parts of the inner surface 52 of the cover 50 and does not contact the back surface 12 at other regions. However, the back surface 12 of the electronic apparatus 10 bulges out to the back, therefore even in regions where the inner surface 52 of the cover 50 and the back surface 12 do not contact, the gap therebetween is small.

It should be noted that, in the present embodiment, when the cover 50 is attached to the back surface 12, it contacts the back surface 12 planarly at the edge parts of the inner surface 52, but it may contact the back surface 12 linearly at the edges of the inner surface 52. Alternatively, the cover 50 may contact the back surface 12 linearly at the edges of the side surface 53 or planarly at the side surface 53 as a whole.

### Action and Effects

In the apparatus-cover system 1 configured as above, if the cover 50 is positioned at the position of attachment on the front surface 11 of the electronic apparatus 10, each third magnet 61 of the cover 50 will have polarity different from the facing first magnet 41. For this reason, the third magnet 61 of the cover 50 is attracted to the first magnet 41 of the electronic apparatus 10 and, as a result, the cover 50 is attached to the front surface 11 of the electronic apparatus 10. Similarly, if the cover 50 is positioned at the position of attachment on the back surface 12 of the electronic apparatus 10, each third magnet 61 of the cover 50 will have polarity different from the facing second magnet 42. For this reason, the third magnet 61 of the cover 50 is attracted to the second magnet 42 of the electronic apparatus 10 and, as a result, the cover 50 is attached to the back surface 12 of the electronic apparatus 10.

In this way, in the present embodiment, the cover 50 can be attached to the front surface 11 and the back surface 12 of the electronic apparatus 10. For this reason, when the electronic apparatus 10 is not being used, the cover 50 may be attached to the front surface 11 to protect the display 15 and the control parts 30 provided at the front surface 11. Further, when the electronic apparatus 10 is being used, the cover 50 can be attached to the back surface 12 and accordingly the cover 50 no longer has to be separately kept from the electronic apparatus 10. Therefore, according to the present embodiment, a user friendly apparatus-cover system 1 is provided.

Further, in the present embodiment, the inner surface 52 of the cover 50 has a shape bulging out in the outer surface direction. For this reason, in the present embodiment, as explained above, when the cover 50 is attached to the front surface 11, a gap is formed between the front surface 11 and the inner surface of the cover 50. As a result, in the present embodiment, when the cover 50 is attached to the front surface 11, the cover 50 can be kept from interfering with the control parts 30 or the cover 50 can be kept from excessively interfering with the control parts 30.

On the other hand, as shown in the cross-sectional view of FIG. 12, when the cover 50 is attached to the back surface 12, the inner surface 52 of the cover 50 extends corresponding to the back surface 12 bulging out from the electronic apparatus 10. If the back surface of the electronic apparatus 10 were flat in shape, when the cover 50 was attached to the back surface, a large gap would be formed between the cover 50 and back surface. As opposed to this, in the present embodiment, the back surface 12 of the electronic apparatus 10 bulges out to the back, therefore it is possible to keep such a gap small and as a result make the volume of the inside of the housing 20 of the electronic apparatus 10 larger and improve the mountability of parts to inside the housing 20. For example, in the present embodiment, the fan 35 is arranged at the region formed by the back surface 12 of the electronic apparatus 10 bulging out to the back, and therefore the space inside the electronic apparatus 10 is effectively used. Therefore, according to the present embodiment, it is possible to make the apparatus-cover system 1 including the cover 50 a compact configuration overall. On this point as well, a user friendly apparatus-cover system 1 is provided. In particular, in the present embodiment, the inner surface 52 of the cover 50 bulges out entirely in the outer surface direction and the back surface 12 of the electronic apparatus 10 bulges out entirely to the back corresponding to the bulge of the inner surface 52, therefore it is possible to further enhance the mountability of parts to the inside of the housing 20.

Further, in the present embodiment, as shown in FIG. 12, when attached to the back surface 12, the cover 50 contacts the back surface 12 at the edge parts of the inner surface 52 of the cover 50 and does not contact the back surface 12 at other regions. If the bulging shape of the inner surface 52 of the cover 50 were made completely the same as the bulging shape of the back surface 12, when the cover 50 were attached to the back surface 12, the locations of contact might become uneven and rattling at the cover 50 might occur due to manufacturing error of the cover 50 or slight deformation occurring along with use. As opposed to this, in the present embodiment, since the back surface 12 is contacted only at the edge parts of the inner surface 52 of the cover 50, the occurrence of rattling at the time of manufacturing error and slight deformation is reduced.

Further, in the present embodiment, the outer surface 51 of the cover 50 also has a shape bulging out in the outer surface direction. For this reason, when the cover 50 is not attached to the back surface 12 of the electronic apparatus 10, the back surface 12 bulges out to the back, and when the cover 50 is attached to the back surface 12 of the electronic apparatus 10, the outer surface 51 of the cover 50 attached to the back surface 12 bulges out to the back. Therefore, when the user holds the electronic apparatus 10, there is little feeling of strangeness over whether the cover 50 is attached or not. In particular, in the present embodiment, the bulging shape of the outer surface 51 of the cover 50 has a shape similar to the bulging shape of the back surface 12 of the electronic apparatus 10, therefore there is particularly little feeling of strangeness over this.

Further, in the present embodiment, the magnets 41, 42, 61 are respectively arranged along the short sides of the front surface 11, back surface 12, and inner surface 52. By the magnets 41, 42, 61 being arranged along the short sides in this way, when the cover 50 is attached to the electronic apparatus 10, the cover 50 is fixed at positions separated from each other, therefore the cover 50 can be stably fixed to the electronic apparatus 10.

In addition, in the present embodiment, a plurality of the magnets 41, 42, 61 are arranged along the corresponding side and the adjoining magnets have different polarities. By the adjoining magnets having different polarities in this way, if the cover 50 is placed on the electronic apparatus 10 offset from the attachment position, the third magnets 61 of the cover 50 and the first magnets 41 or second magnets 42 of the electronic apparatus 10 facing the third magnets 61 will have the same polarities, therefore will repel each other. As a result, the cover 50 can be guided to the correct attachment position. In particular, in the present embodiment, odd numbers of magnets 41, 42, 61 are arranged along the corresponding side. For this reason, even when the cover 50 is offset to either the top or bottom of the electronic apparatus 10, the cover 50 can be guided to the correct attachment position.

Further, in the present embodiment, the distances between adjoining magnets 41, 42, 61 are shorter than the lengths of the magnets extending along the corresponding sides. As a result, even if the cover 50 is placed on the electronic apparatus 10 slightly offset from the attachment position, a large repulsive force will act and the cover 50 will be guided to the correct attachment position. In addition, in the present embodiment, the center-most magnet among the odd number of magnets 41, 42, 61 arranged along each side are arranged at the center of the side and the magnets arranged at both sides of the center-most magnet are positioned at equal distances therefrom. Further, in the present embodiment, the first magnets 41, second magnets 42, and third magnets 61 are arranged respectively point symmetrically. By the magnets 41, 42, 61 being arranged in this way, even if the cover 50 is reversed right and left from a certain attachment position (that is, even if the cover 50 is rotated 180°), the cover 50 can be attached to the electronic apparatus 10. Therefore, the user friendliness when attaching the cover 50 to the electronic apparatus 10 becomes better.

### Modifications

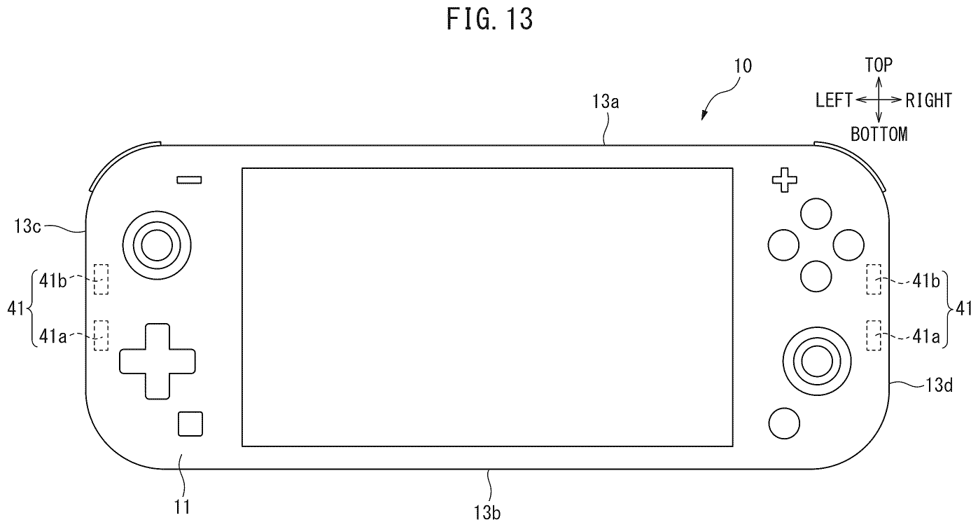

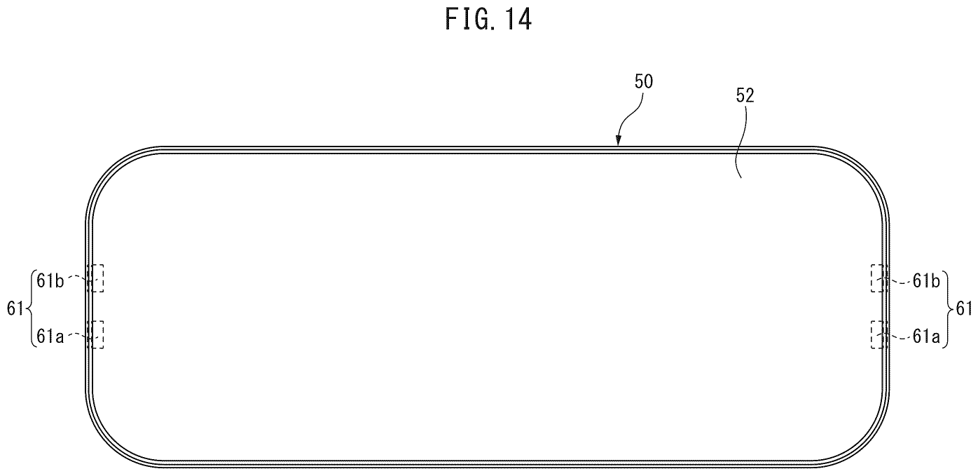

In the above embodiments, odd number of magnets 41, 42, 61 are arranged along the corresponding side. However, even number of magnets 41, 42, 61 may be arranged along the side such as shown in FIGS. 13 and 14. FIG. 13 is a plan view, similar to FIG. 5, of an electronic apparatus 10 in which two first magnets 41 are arranged along each side. The second magnets 42 are arranged at the same positions as the first magnets 41 in the plan view of FIG. 13 (deep behind first magnets 41). Further, FIG. 14 is a plan view, similar to FIG. 9, of a cover 50 in which two third magnets 61 are arranged along each side.

In the example shown in FIGS. 13 and 14, the two magnets 41, 42, 61 arranged along each side are arranged at both sides from the center of the short side so that the distances from the center of the short side are equal to each other. Further, if there are even numbers of greater or equal to four magnets arranged along each side, the pairs of magnets arranged along each side are arranged at both sides from the center of the short side so that the distances from the center of the short side are equal to each other. In this case as well, the adjoining magnets are arranged to be different in polarities.

Further, in the above embodiment, a plurality of the magnets 41, 42, 61 are arranged along the corresponding side, but just single one may be arranged along the side. Furthermore, in the above embodiments, the magnets 41, 42, 61 are arranged along the short sides of the front surface 11, back surface 12, and inner surface 52, but may be arranged along the long sides of the same. In addition, in the above embodiments, the magnets 41, 42, 61 are arranged along the short sides of the front surface 11, back surface 12, and inner surface 52, that is, along the outer peripheries of the front surface 11, back surface 12, and inner surface 52, but may be arranged at the relatively inside regions.

Further, in the above embodiment, the distances between adjoining magnets 41, 42, 61 are shorter than the lengths of the magnets along the corresponding side. However, the distances between adjoining magnets may be longer than the lengths of the magnets along the corresponding side. Further, in the above embodiments, the magnets 41, 42, 61 arranged along each short side are arranged so that the center-most magnet among them are positioned at the center of the short sides. However, the center-most magnet may not be positioned at the center of each short side but be arranged at a position offset to a side toward one of the long sides. In this case, the magnets 41, 42, 61 may be arranged point symmetrically as explained above. If arranged point symmetrically, even if the electronic apparatus 10 or the cover 50 is rotated 180°, the arrangement of the magnets 41, 42, 61 is the same.

Further, in the above embodiment, all of the first magnets 41, second magnets 42, and third magnets 61 are magnets (hard magnetic members), but some of these may be soft magnetic members. However, the first magnetic members, second magnetic members, and third magnetic members respectively corresponding to the first magnets 41, second magnets 42, and third magnets 61 have to be configured so that the third magnetic members are attracted to the first magnetic members or second magnetic members. Therefore, if the first magnetic members and second magnetic members are soft magnetic members, the third magnetic members are hard magnetic member, while if the third magnetic members are soft magnetic member, the first magnetic members and second magnetic members are hard magnetic member. Further, in other embodiments, some or all of the magnetic members may be electromagnets.

Further, the electronic apparatus 10 may have a Hall sensor (not shown) detecting a magnetic field formed by the third magnets 61. The Hall sensor can detect whether the cover 50 is attached to the front surface 11 or back surface 12 of the electronic apparatus 10 based on a detected magnetic field. By such a Hall sensor being connected to the control device of the electronic apparatus 10, the control device may control the electronic components of the electronic apparatus 10 including the display 15 based on the state of attachment of the cover 50 to the front surface 11 or back surface 12.

Specifically, for example, the control device may awaken the electronic apparatus 10 from a sleep state when it is detected that the cover 50 has been detached from the front surface 11 of the electronic apparatus 10. Alternatively, the control device may awaken the electronic apparatus 10 from a sleep state when it is not detected that the cover 50 has been attached to the front surface 11 of the electronic apparatus 10 and it is detected that the cover 50 is attached to the back surface 12. Further, the control device may render the electronic apparatus 10 the sleep state when it is detected that the cover 50 has been attached to the front surface 11 of the electronic apparatus 10. Alternatively, the control device may render the electronic apparatus 10 the sleep state when it is detected that the cover 50 is attached to the front surface 11 of the electronic apparatus 10 and the cover 50 is not attached to the back surface 12.

In addition, if a camera is provided at the back surface 12 of the electronic apparatus 10, the control device connected to the camera may start up the camera when it is not detected that the cover 50 is attached to the front surface 11 of the electronic apparatus 10 and it is detected that the cover 50 has been detached from the back surface 12. Further, the control device may make the operation of the camera stop when it is detected that the cover 50 has been attached to the back surface 12 during operation of the camera. Alternatively, the control device may make the operation of the camera stop when it is detected that the cover 50 has been attached to the front surface 11 during operation of the camera.

Further, in the above embodiment, a set of first magnets 41 are provided at the front surface 11 side of the electronic apparatus 10, while a set of second magnets 42 are provided at the back surface 12 side. Accordingly, two sets of magnets are provided. However, just one set of magnets may be provided between the front surface 11 and back surface 12. In this case, the third magnets 61 provided at the cover 50 are attracted to the same magnets of the electronic apparatus 10 both when the cover 50 is attached to the front surface 11 side of the electronic apparatus 10 and when the cover 50 is attached to the back surface 12 side thereof.

Furthermore, in the above embodiment, the fan 35 is arranged at a region of the inside of the back wall 22 formed by the back wall 22 having a shape bulging out toward the back. However, other components may be arranged in this region in addition to the fan 35 or in place of the fan 35.

Further, in the above embodiment, the cover 50 is configured to contact the front surface 11 or back surface 12 of the electronic apparatus 10 at the edges or edge parts of the inner surface 52 when attached to the electronic apparatus 10. However, the cover 50 may be configured to contact the front surface 11 or back surface 12 of the electronic apparatus 10 not only at the edges or edge parts, but also at the inner surface 52 other than the edges and edge parts.

Furthermore, in the above embodiment, the cover 50 has a shape bulging out entirely in the outer surface direction gently. However, the cover 50 may have a shape having, in addition to a portion having such a shape, a ring shaped portion extending from the edge thereof to the inner surface direction (see FIGS. 8 and 10). In a cover 50 configured in this way, when the cover 50 is attached to the electronic apparatus 10, the ring shaped part is positioned on the side surface 13 of the electronic apparatus 10.

### Second Embodiment

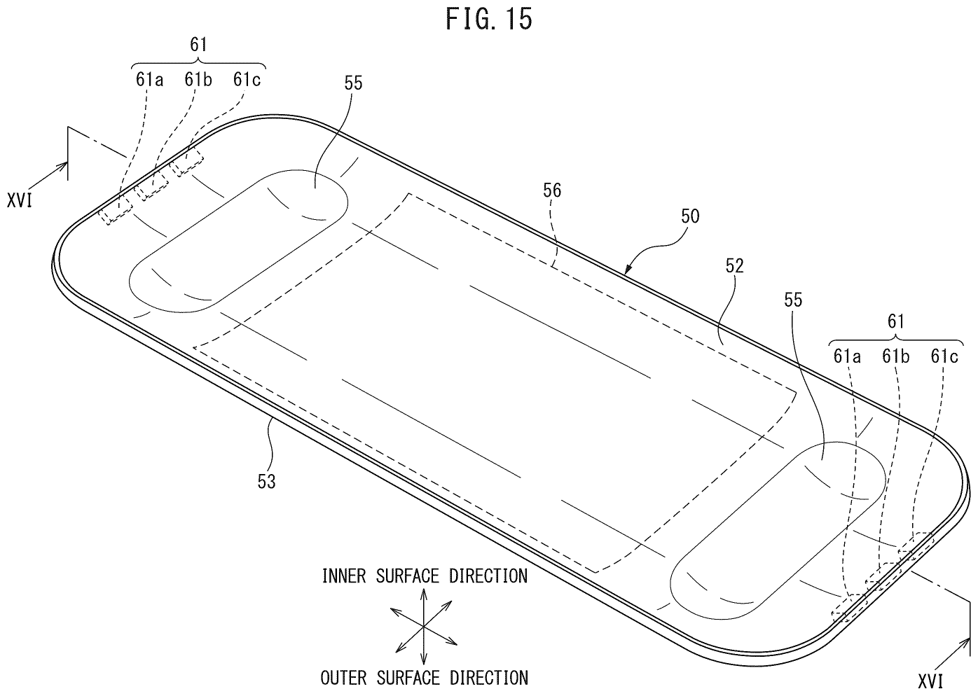

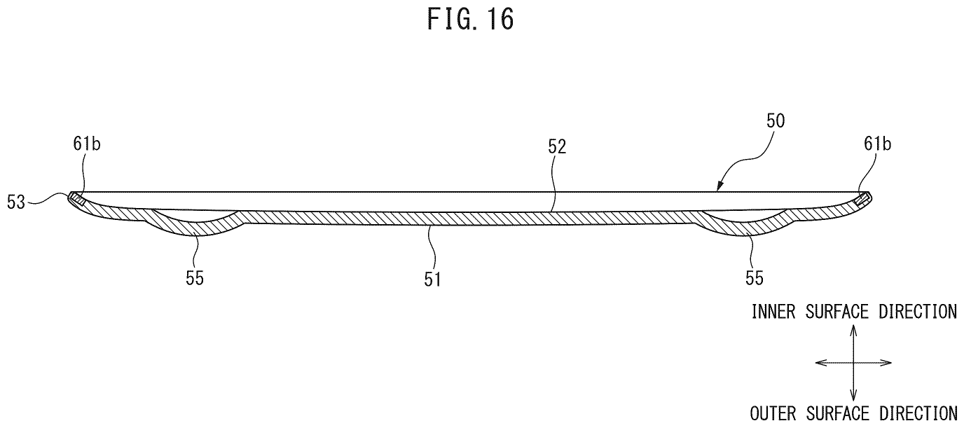

Next, referring to FIGS. 15 and 16, an apparatus-cover system 1 according to a second embodiment will be explained. The configuration of the apparatus-cover system 1 according to the second embodiment is basically similar to the configuration of the apparatus-cover system 1 according to the first embodiment. Below, the points different from the apparatus-cover system 1 according to the first embodiment will be focused on in the explanation.

FIG. 15 is a perspective view, similar to FIG. 8, of an inner surface side of a cover 50 according to a second embodiment. Further, FIG. 16 is a cross-sectional view of a cover 50 according to the second embodiment seen along a plane XVI-XVI of FIG. 15.

As shown in FIGS. 15 and 16, in the same way as the cover of the first embodiment, the cover 50 has a shape bulging out entirely in the outer surface direction. In addition, the cover 50 has specific regions 55 bulging out in the outer surface direction compared with the region facing the display 15 when the cover 50 is attached to the front surface of the electronic apparatus 10 (region 56 shown by the broken lines in FIG. 15, below, referred to as the “facing region”).

Therefore, the outer surface 51 and inner surface 52 of the cover 50 have specific regions 55 bulging out toward the outer surface direction compared with the facing region 56. In particular, in the present embodiment, the outer surface 51 and inner surface 52 have shapes bulging out, in the specific regions 55, further to the outer surface direction compared with regions other than the specific regions 55. Further, in the present embodiment, the specific regions 55 are respectively positioned at both sides across the facing region 56. Further, the specific regions 55 extend in the direction of the short sides of the cover 50. In other words, the specific regions 55 extend in the top-bottom direction, that is, in a direction perpendicular to the direction in which the specific regions 55 are arranged across the facing region 56 (long side direction) when the cover 50 is attached to the front surface of the electronic apparatus 10.

Further, in the present embodiment, two specific regions 55 are positioned symmetrically across the facing region 56. Specifically, two specific regions 55 are positioned symmetrically about the center of the cover 50 in the long side direction. Further, in the present embodiment, two specific regions 55 are positioned point symmetrically about the center of the cover 50. In particular, in the present embodiment, the specific regions 55 are arranged at positions facing the first control parts 31 and second control parts 32 provided at the front surface 11 when the cover 50 is attached to the front surface 11 of the electronic apparatus 10.

In the present embodiment, the specific regions 55 are arranged at both sides across the facing region 56. Further, the first control parts 31 and second control parts 32 are provided at both of the left and right sides across the display 15. For this reason, the specific regions 55 bulging out toward the outer surface direction are positioned on the first control parts 31 and second control parts 32 when the cover 50 is attached to the front surface 11 of the electronic apparatus 10. Therefore, the cover 50 can be attached entirely without interfering with or without excessively interfering with the first control parts 31 and second control parts 32 protruding to the front. In addition, when the cover 50 is attached to the back surface 12 of the electronic apparatus 10, at the specific regions 55, the outer surface 51 protrudes to the back. As a result, the user more easily grips the electronic apparatus 10 to which the cover 50 is attached. In particular, when the cover 50 is attached to the back surface 12 of the electronic apparatus 10, the specific regions 55 extend in the top-bottom direction, therefore the user holding the electronic apparatus 10 from the both of the left and right sides of the electronic apparatus 10 easily holds the electronic apparatus 10.

Further, in the present embodiment, the outer surface 51 and inner surface 52 of the cover 50 bulge out entirely toward the outer surface direction and bulge out toward the further outer surface direction in the specific regions compared with other regions. Therefore, according to the cover 50 of the present embodiment, it is possible to further improve the mountability of components in the housing 20 while the user can easily hold the electronic apparatus 10.

It should be noted that, in the above embodiments, the cover 50 is formed so as to bulge out entirely toward the outer surface direction. However, the cover 50 may be formed so as to bulge out toward the outer surface direction at only the specific regions 55.

Above, preferred embodiments according to the present invention were explained, but the present invention is not limited to these embodiments and can be corrected and changed in various ways within the language of the claims.

1. A system comprising an electronic apparatus and a cover, wherein
the electronic apparatus include:
a front surface provided with a display;
control parts protruding forward from the front surface;
a back surface provided at an opposite side from the front surface;
a first magnetic member provided at an edge part on the front surface side; and
a second magnetic member provided at an edge part on the back surface side,
the back surface has a shape bulging out backward,
the cover includes:
a third magnetic member attracted to either the first magnetic member or the second magnetic member, the cover being configured to be detachably attached to the front surface of the electronic apparatus by the third magnetic member being attracted to the first magnetic member and to be detachably attached to the back surface of the electronic apparatus by the third magnetic member being attracted to the second magnetic member;
an outer surface which is exposed when the cover is attached to the front surface of the electronic apparatus and when the cover is attached to the back surface of the electronic apparatus; and
an inner surface facing the front surface of the electronic apparatus when the cover is attached to the front surface and facing the back surface of the electronic apparatus when the cover is attached to the back surface, and
the inner surface having a shape bulging out in a outer surface direction which is the direction from the inner surface toward the outer surface.

2. The system according to claim 1, wherein the outer surface of the cover has a shape bulging out in the outer surface direction corresponding to the shape of the inner surface.

3. The system according to claim 2, wherein
the control parts protrude forward at both sides across the display, and
the outer surface and the inner surface of the cover have shapes wherein, compared with a region facing the display when the cover is attached to the front surface, specific regions positioned at both sides across the region bulge out further in the outer surface direction.

4. The system according to claim 3, wherein
the specific regions extend symmetrical across the region facing the display and in directions perpendicular to a direction across the region facing the display.

5. The system according to claim 3, wherein
the inner surface and the outer surface of the cover bulge out entirely in the outer surface direction and have shapes bulging out further at the specific regions in the outer surface direction compared with other regions of the inner surface and the outer surface.

6. The system according to claim 1, wherein
the back surface of the electronic apparatus has a shape bulging out backward entirely and the inner surface of the cover has a shape bulging out entirely in the outer surface direction.

7. The system according to claim 1, wherein
the first magnetic members are arranged along each of opposite sides of the front surface,
the second magnetic members are arranged along each of opposite sides of the back surface, and
the third magnetic members are arranged along each of opposite sides of the cover.

8. The system according to claim 7, wherein
a plurality of the first magnetic members are arranged along each of the opposite sides of the front surface,
a plurality of the second magnetic members are arranged along each of the opposite sides of the back surface,
a plurality of the third magnetic members are arranged along each of the opposite sides of the cover, and
the first magnetic members, the second magnetic members, and the third magnetic members are all magnets, and adjoining magnetic members among the plurality of the magnetic members arranged along each side differ in polarities.

9. The system according to claim 8, wherein
odd numbers of the first magnetic members are arranged along each of the opposite sides of the front surface,
odd numbers of the second magnetic members are arranged along each of the opposite sides of the back surface, and
odd numbers of the third magnetic members are arranged along each of the opposite sides of the cover.

10. The system according to claim 9, wherein
the center-most magnetic member among the odd number of magnetic members arranged along each side are positioned at center of the side.

11. The system according to claim 9, wherein
a pair of the magnetic members arranged at both sides of the center-most magnetic member among the odd number of magnetic members arranged along each side are positioned at the equal intervals with each other from the center-most magnetic member.

12. The system according to claim 8, wherein
distances between adjoining magnetic members among magnetic members including the first magnetic members, the second magnetic members, and the third magnetic members are shorter than lengths of the magnetic members along the corresponding sides.

13. The system according to claim 7, wherein
the plurality of the first magnetic members are arranged point symmetrically about the center of the front surface, the plurality of the second magnetic members are arranged point symmetrically about the center of the back surface, and the plurality of the third magnetic members are arranged point symmetrically about the center of the cover.

14. The system according to claim 1, wherein
the electronic apparatus further has a side surface provided between the front surface and the back surface so as to connect the front surface and the back surface, a housing defining the front surface, back surface, and side surface, and a fan provided inside the housing,
the housing has a back wall defining the back surface and bulging out to the back,
the fan is arranged at a region formed inside the housing by the back wall bulging out, and
an air ventilation opening is provided at the side surface, and the air ventilation opening is arranged at a position at least partially overlapping the air ventilation port of the fan when viewing the electronic apparatus from the side surface side where that air ventilation opening is provided.

15. A cover able to be attached to an electronic apparatus having a front surface provided with a display and a back surface provided at an opposite side from the front surface, which cover:
is configured to be detachably attached to the front surface of the electronic apparatus and to be detachably attached to the back surface of the electronic apparatus,
includes an outer surface which is exposed when the cover is attached to the front surface of the electronic apparatus and when the cover is attached to the back surface of the electronic apparatus,
includes an inner surface facing the front surface and back surface when the cover is attached to the front surface of the electronic apparatus and when the cover is attached to the back surface of the electronic apparatus and having a shape bulging out in an outer surface direction which is a direction toward the outer surface side with respect to the cover, and
third magnetic member attracted to first magnetic member provided at an edge part of a front surface side of the electronic apparatus and to second magnetic member provided at an edge part at a back surface side of the electronic apparatus.
